(19) United States
(12) Patent Application Publication
(10) Pub. No.: US 2025/0142886 A1
(43) Pub. Date: May 1, 2025

(54) Thin Film Transistor, Display Panel and Display Device

(71) Applicant: BOE TECHNOLOGY GROUP CO., LTD., Chaoyang District, Beijing (CN)

(72) Inventors: Guangcai Yuan, Beijing (CN); Lingyan Liang, Beijing (CN); Hongtao Cao, Beijing (CN); Fengjuan Liu, Beijing (CN); Ce Ning, Beijing (CN); Fei Wang, Beijing (CN); Hehe Hu, Beijing (CN); Hengbo Zhang, Beijing (CN)

(21) Appl. No.: 18/686,647

(22) PCT Filed: Aug. 27, 2021
(86) PCT No.: PCT/CN2021/115156

§ 371 Date: Feb. 26, 2024

(51) Int. Cl. H10D 30/67; H10D 62/10; H10D 86/40

(52) U.S. Cl. CPC H10D 30/6755; H10D 62/124; H10D 86/423

(57) ABSTRACT

A thin film transistor includes a substrate; and a semiconductor layer a gate, a source electrode and a drain electrode; which are arranged on the substrate. The semiconductor layer includes a first material layer and a second material layer which are stacked, wherein a material of the first material layer is selected from one of or a combination of first n-type metal oxide semiconductor materials, and a material of the second material layer is selected from one of or a combination of second n-type metal oxide semiconductor materials. A carrier mobility of a first n-type metal oxide semiconductor material is greater than or equal to 40 cm²/Vs, and a second n-type metal oxide semiconductor material is doped with Y, Y being selected from one of or a combination of rare earth elements. The first material layer is closer to the gate than the second material layer.

### CROSS-REFERENCE TO RELATED APPLICATION

This application is the United States national phase of International Patent Application No. PCT/CN2021/115156, filed Aug. 27, 2021, the disclosure of which is hereby incorporated by reference in its entirety.

### BACKGROUND OF THE INVENTION

### Field of the Invention

The present disclosure relates to the field of semiconductor technologies, and in particular, to a thin film transistor, a display panel and a display device.

### Description of Related Art

Thin film transistors (TFTs) are semiconductor devices usually used in flat panel displays. As a pixel control and driving device in flat panel displays, the thin film transistor affects the development of the flat panel displays.

### SUMMARY OF THE INVENTION

In an aspect, a thin film transistor is provided. The thin film transistor includes: a substrate; and a semiconductor layer, a gate, a source and a drain that are disposed on the substrate. The semiconductor layer includes a first material layer and a second material layer that are stacked. A material of the first material layer is selected from one or a combination of first n-type metal oxide semiconductor materials, and a material of the second material layer is selected from one or a combination of second n-type metal oxide semiconductor materials. A carrier mobility of a first n-type metal oxide semiconductor material is greater than or equal to 40 cm²/Vs. A second n-type metal oxide semiconductor material is doped with Y, and the Y is selected from one or a combination of rare earth elements. The first material layer is closer to the gate than the second material layer.

In some embodiments, a doping ratio of the Y in the second n-type metal oxide semiconductor material is in a range of 0.01 at % to 0.30 at %, inclusive.

In some embodiments, a type of rare earth element is selected as the Y, and the doping ratio of the type of rare earth element in the second n-type metal oxide semiconductor material is in a range of 0.01 at % to 0.30 at %, inclusive.

In some embodiments, a combination of multiple types of rare earth elements are selected as the Y, and the doping ratio of the combination of the multiple types of rare earth elements in the second n-type metal oxide semiconductor material is in a range of 0.01 at % to 0.30 at %, inclusive.

In some embodiments, the first n-type metal oxide semiconductor material is doped with Z, the Z is selected from one or a combination of rare earth elements, and a type of a rare earth element added to the first n-type metal oxide semiconductor material is same as or different from a type of a rare earth element added to the second n-type metal oxide semiconductor material.

In some embodiments, types of elements included in the first material layer are same as types of elements included in the second material layer, and a ratio of numbers of atomics of all elements included in the first material layer is different from a ratio of numbers of atomics of all elements included in the second material layer.

In some embodiments, the first n-type metal oxide semiconductor material is selected from metal oxides doped with X or not doped with X. The metal oxides each include one or more of an indium element, a zinc element, a tin element and a gallium element, and an oxide element; and the X is selected from one or a combination of aluminum, tungsten, hafnium, tantalum, zirconium, nitrogen and hydrogen.

In some embodiments, a thickness of the second material layer is greater than 10 nm.

In some embodiments, in a case where the thickness of the second material layer is greater than 10 nm and less than or equal to 15 nm, a ratio of a thickness of the first material layer to the thickness of the second material layer is less than or equal to 1.

In some embodiments, as the ratio of the thickness of the first material layer to the thickness of the second material layer gradually increases, a carrier mobility of the thin film transistor increases.

In some embodiments, in a case where the thickness of the second material layer is greater than 15 nm, a thickness of the first material layer is greater than or equal to 20 nm, and a ratio of the thickness of the first material layer to the thickness of the second material layer is less than or equal to 2.

In some embodiments, a thickness of the first material layer is greater than or equal to 10 nm.

In some embodiments, a thickness of the semiconductor layer is in a range of 30 nm to 70 nm, inclusive.

In another aspect, a display panel is provided. The display panel includes the thin film transistor as described above.

In yet another aspect, a display device is provided. The display device includes the display panel as described above.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1A is a sectional view showing a structure of a bottom-gate thin film transistor, in accordance with some embodiments;

FIG. 1B is a sectional view showing a structure of a top-gate thin film transistor, in accordance with some embodiments;

FIG. 2A is a schematic diagram of a thin film transistor transforming from a depletion layer to an inversion layer, in accordance with some embodiments;

FIG. 2B is a schematic diagram of a thin film transistor transitioning from a linear region to a saturation region, in accordance with some embodiments;

FIG. 2C is a graph of output characteristics of a thin film transistor under different gate voltages, in accordance with some embodiments;

FIG. 2D is an energy band structural diagram under negative gate-bias illumination stress (NBIS) based on a photo-generated hole-electron pairs theory, in accordance with some embodiments;

FIG. 3A is a sectional view showing a structure of another bottom-gate thin film transistor, in accordance with some embodiments;

FIG. 3B is a sectional view showing a structure of another top-gate thin film transistor, in accordance with some embodiments;

FIG. 4A is a comparison diagram of transfer characteristic curves of thin film transistors in Comparative Example 1, Comparative Example 2 and Experimental Example 3;

FIG. 4B is a stability test chart of a thin film transistor in Comparative Example 1 under a NBIS condition;

FIG. 4C is a stability test chart of a thin film transistor in Comparative Example 2 under a NBIS condition;

FIG. 4D is a comparison diagram of transfer characteristic curves of thin film transistors in Experimental Example 1 to Experimental Example 4;

FIG. 4E is a stability test chart of a thin film transistor in Experimental Example 1 under a NBIS condition;

FIG. 4F is a stability test chart of a thin film transistor in Experimental Example 2 under a NBIS condition;

FIG. 4G is a stability test chart of a thin film transistor in Experimental Example 3 under a NBIS condition;

FIG. 4H is a stability test chart of a thin film transistor in Experimental Example 4 under a NBIS condition;

FIG. 4I is a comparison diagram of transfer characteristic curves of thin film transistors in Experimental Example 4 to Experimental Example 6;

FIG. 4J is a stability test chart of a thin film transistor in Experimental Example 5 under a NBIS condition; and

FIG. 4K is a stability test chart of a thin film transistor in Experimental Example 6 under a NBIS condition.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

Some embodiments of the present disclosure provide a display device. The display device includes a display panel. Of course, the display device may further include other components. For example, the display device may include a circuit for providing electrical signals for the display panel to drive the display panel for display. The circuit may be called a control circuit, and may include a circuit board and/or an integrated circuit (IC) electrically connected to the display panel.

For example, the display panel may be one of a liquid crystal display (LCD) panel, an organic light-emitting diode (OLED) display panel, a quantum dot light-emitting diode (QLED) display panel, a micro light-emitting diode (micro LED) display panel and a mini light-emitting diode (mini LED) display panel.

The display device may specifically be a mobile phone, a tablet computer, a notebook computer, a personal digital assistant (PDA), a vehicle-mounted computer, a laptop computer, or a digital camera, etc.

The display panel includes a base substrate and driving circuits (such as pixel driving circuits or gate driving circuits) provided on the base substrate. For example, the driving circuit may include thin film transistor(s) (TFT(s)). The thin film transistor is an important component for composing the pixel driving circuit or the gate driving circuit. During a power-on process, by controlling the thin film transistor(s) to be turned on or turned off, the pixel driving circuit and the gate driving circuit may be controlled to drive the display panel for display.

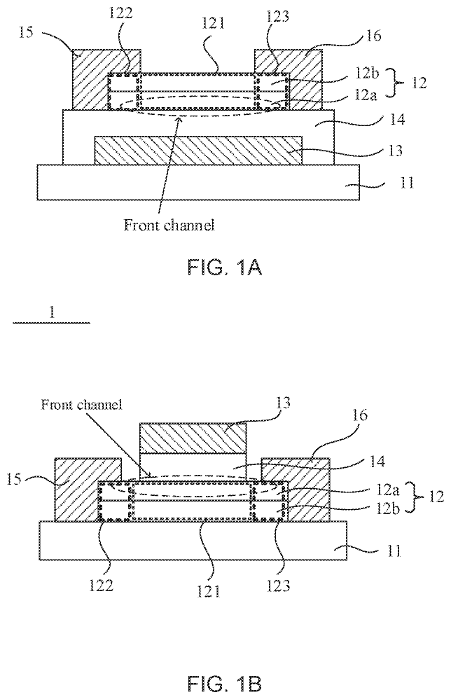

As shown in FIGS. 1A and 1B, the thin film transistor 1 includes a substrate 11, and a semiconductor layer 12, a gate 13, a gate insulating layer 14, a source 15 and a drain 16 that are provided on the substrate 11. The substrate 11 may be a portion of the above base substrate. Depending on that the above display panel is a flexible display panel or a rigid display panel, the substrate 11 may be a flexible substrate or a rigid substrate. For example, the flexible substrate may be a plastic substrate or a flexible substrate with a certain thickness made of glass or a metal material. For example, the rigid substrate may be a glass substrate or a semiconductor substrate.

According to the upper and lower positions between the gate 13 and the semiconductor layer 12 in the thin film transistor 1, the thin film transistor 1 may include a bottom-gate thin film transistor and a top-gate thin film transistor. As shown in FIG. 1A, for a bottom-gate thin film transistor, the gate 13 is disposed below the semiconductor layer 12, that is, the gate 13 is closer to the substrate 11 than the semiconductor layer 12. As shown in FIG. 1B, for a top-gate thin film transistor, the gate 13 is disposed above the semiconductor layer 12, that is, the semiconductor layer 12 is closer to the substrate 11 than the gate 13.

In some embodiments, as shown in FIGS. 1A and 1B, the semiconductor layer 12 includes a channel region 121, and a source region 122 and a drain region 123. The source region 122 and the drain region 123 are located on two opposite sides of the channel region 121. The source 15 and the drain 16 are disposed in the same layer. The source 15 and the drain 16 are disposed on a side of the semiconductor layer 12 proximate to the substrate 11, and the source 15 and the drain 16 are respectively in contact with the source region 122 and the drain region 123 of the semiconductor layer 12. Alternatively, as shown in FIGS. 1A and 1B, the source 15 and the drain 16 are disposed on a side of the semiconductor layer 12 away from the substrate 11, and the source 15 and the drain 16 are respectively in contact with the source region 122 and the drain region 123 of the semiconductor layer 12.

Considering an n-type thin film transistor as an example, the working principle of the thin film transistor 1 is as follows.

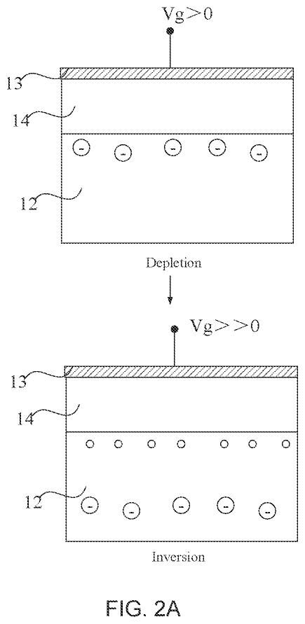

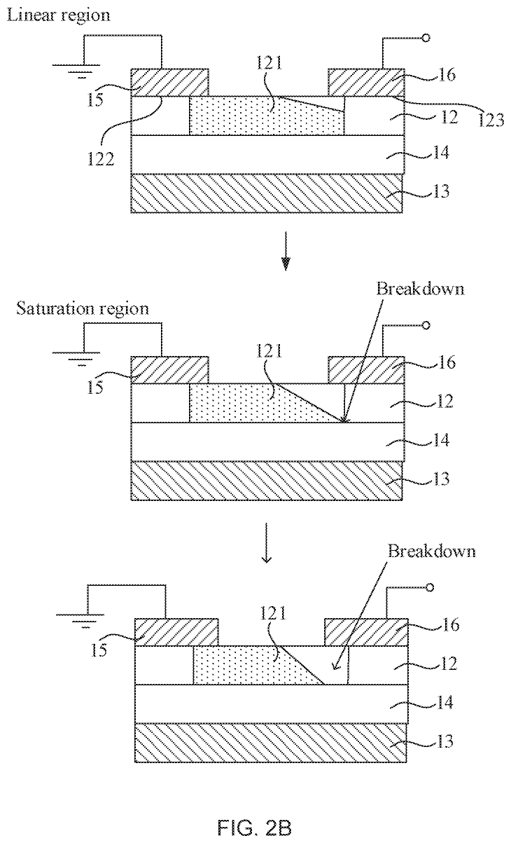

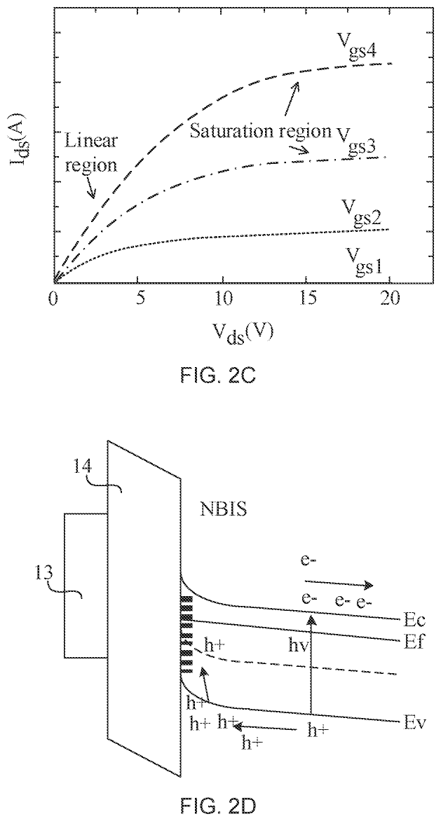

As shown in FIG. 2A, when a positive voltage is applied to the gate 13, the gate voltage generates an electric field in the gate insulating layer 14, the electric force lines are directed from the gate 13 to a surface of the semiconductor, and induced charges are created at the surface. As the gate voltage increases, the surface of the semiconductor will transform from a depletion layer to an electron accumulation layer to form an inversion layer. When a strong inversion is reached (the required gate voltage is called a threshold voltage Vₜₕ of the thin film transistor 1, i.e., reaching a turn-on voltage), a conductive channel is formed in the inversion layer between the source 15 and the drain 16, that is, commonly known as the front channel. Carriers will pass through the channel when a voltage is applied between the source 15 and the drain 16. As shown in FIGS. 2B and 2C, when a source-drain voltage Vas is very small, the conductive channel is approximately a constant resistance, and a leakage current increases linearly as the source-drain voltage increases, corresponding to a linear region of the thin film transistor 1. When the source-drain voltage Vas is very large, the source-drain voltage Vas will affect the gate voltage, so that the electric field in the gate insulating layer 14 is caused to gradually weaken from an end of the source to an end of the drain, and electrons in the inversion layer on the surface of the semiconductor is caused to gradually decrease from the end of the source to the end of the drain. Therefore, the resistance of the channel increases as the source-drain voltage V_{ds} increases. The increase of the leakage current becomes slow, corresponding to transition from the linear region to a saturation region. When the source-drain voltage Vas increases to a certain level, a thickness of the inversion layer at the end of the drain is reduced to zero. As the source-drain voltage Vas continues to increase, the device (i.e., the thin film transistor) enters the saturation region. Due to action of the source-drain positive voltage, the electrons from the source 15 flow through the channel to form an electron flow, which is a turn-on state of the thin film transistor 1.

Therefore, a working region of the turned-on thin film transistor 1 is divided into a non-saturation and a saturated region. In a case where V_{gs} is greater than Vₜₕ (V_{gs}>Vₜₕ) and Vas is less than a difference between V_{gs} and Vₜₕ (V_{ds}<V_{gs}−Vₜₕ), the thin film transistor 1 works in the non-saturation, and the corresponding current of the non-saturation is shown in the following formula (1). In a case where Vas is greater than a difference between V_{gs} and Vₜₕ (V_{ds}>V_{gs}−Vₜₕ) and V_{gs} is greater than Vₜₕ (V_{gs}>Vₜₕ), the thin film transistor 1 works in the saturation region, and the corresponding current of the saturation region is shown in the following formula (2). In the formulas, u is electron mobility, Cₒₓ is a capacitance per unit area of the metal-insulating layer-semiconductor (MIS) structure of the thin film transistor, and W/L represents a ratio of a channel width to a channel length of the thin film transistor. Of course, in a case where an inversion channel is not formed, the thin film transistor is in a cutoff region.

$${I}_{ds} = μ \cdot {C}_{OX} \cdot \frac{W}{L} ( {V}_{gs} - {V}_{th} - \frac{1}{2} {V}_{ds} ) {V}_{ds} . \qquad ( 1 )$$

$${I}_{ds} = \frac{1}{2} μ \cdot {C}_{OX} \cdot \frac{W}{L} {( {V}_{gs} - {V}_{th} )}^{2} . \qquad ( 2 )$$

In the display panel (such as the liquid crystal display panel), the thin film transistor 1 works in the non-saturation region most of the time. It can be seen from the formula (1) that in order to increase an on-state current Iₒₙ (i.e., I_{ds} in the above formula (1) and formula (2)) of the thin film transistor, values of μ, Cₒₓ, W/L, V_{gs} and V_{ds} may increase, or a value of Vₜₕ may decrease. In addition to V_{gs} and V_{ds}, other parameters may all be controlled through process design or structural design.

In addition, the thin film transistor 1 works in a turn-off state (i.e., under a negative gate bias) most of the time. It is found through research that if the thin film transistor 1 is under the negative gate bias for a long time, the threshold voltage of the thin film transistor 1 will drift negatively and the leakage current will increase significantly, so that the device characteristics of the thin film transistor 1 deteriorate. In particular, as shown in FIG. 2D, photo-generated carriers, namely electron-hole pairs, will be generated in the metal oxide semiconductor layer (i.e., the semiconductor layer 12) under illumination. The electrons move toward the drain 16 and the holes move toward the source 15, so that a hole leakage current is produced, and the negative drift of the threshold voltage of the thin film transistor is aggravated.

It can be seen that in order to improve the performance of the thin film transistor 1, it is not only necessary to increase the on-state current of the thin film transistor, but also to improve the light stability of the thin film transistor.

In light of this, in some embodiments, as shown in FIGS. 1A and 1B, the semiconductor layer 12 includes a first material layer 12a and a second material layer 12b that are stacked. A material of the first material layer 12a is selected from one or a combination of first n-type metal oxide semiconductor materials, and a material of the second material layer 12b is selected from one or a combination of second n-type metal oxide semiconductor materials. The carrier mobility of the first n-type metal oxide semiconductor material is greater than or equal to 40 cm²/Vs. The second n-type metal oxide semiconductor material is doped with Y, and the Y is selected from one or a combination of rare earth elements. The first material layer 12a is closer to the gate 13 than the second material layer 12b. As shown in FIG. 1A, the first material layer 12a is located below the second material layer 12b. As shown in FIG. 1B, the first material layer 12a is located above the second material layer 12b.

For the carrier mobility of the material of the first material layer 12a, a graph of I_{ds}^{1/2} versus V_{gs} (I_{ds}^{1/2}˜V_{gs}) is made for the transfer characteristic curve, wherein the formula is shown in the following formula (3), the straight line segment is fit, and the electron mobility μ may be extracted according to a slope of an extrapolated curve. The calculation formula of μ may be shown in the following formula (4).

$$\sqrt{{I}_{ds}} = \sqrt{\frac{W}{2 L} \cdot μ \cdot {C}_{OX}} ( {V}_{gs} - {V}_{th} ) . \qquad ( 3 )$$

$$B = \sqrt{\frac{W}{2 L} \cdot μ \cdot {C}_{OX}} and$$

$$μ = \frac{2 {B}^{2}}{( W / L ) {C}_{OX}} . \qquad ( 4 )$$

In some embodiments, the first n-type metal oxide semiconductor material is selected from metal oxides doped with X or not doped with X. The metal oxide includes one or more of an indium element, a zinc element, a tin element and a gallium element, and an oxide element, and the X is selected from one or a combination of aluminum, tungsten, hafnium, tantalum, zirconium, nitrogen and hydrogen.

The metal oxide includes one or more of the indium element, the zinc element, the tin element and the gallium element, and the oxide element, which means that the metal oxide may be a unary metal oxide such as indium oxide, zinc oxide, tin oxide and gallium oxide, or a binary metal oxide such as indium zinc oxide (IZO) and indium tin oxide (InSnO or ITO), or a ternary metal oxide such as indium gallium zinc oxide (IGZO), indium zinc tin oxide (ITZO) and indium gallium tin oxide (InGaSnO). Of course, the metal oxides may also be a combination of two or more of the unary metal oxide, the binary metal oxide and the ternary metal oxide as described above. The metal oxide doped with X may be obtained by a target sputtering process. In a case where the X is a metal such as aluminum, the target may be an alloy containing X or a compound of X (e.g., aluminum oxide). In a case where X is nitrogen, the sputtering process may be carried out in a nitrogen atmosphere.

In these embodiments, the carrier mobility of the material of the first material layer 12a may be more than 40 cm²/Vs, thereby ensuring a relatively high carrier mobility of the thin film transistor 1 during working.

The rare earth elements are a general term for 17 special elements, and are named because that Swedish scientists used rare earth compounds when extracting the rare earth elements.

The rare earth elements include lanthanides, and elements yttrium (Y) and scandium (Sc) that are closely related to the lanthanides. The lanthanides refer to lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), a total of 15 elements.

The second n-type metal oxide semiconductor material is doped with Y, which means that the second n-type metal oxide semiconductor material may be any metal oxide semiconductor material doped with Y. For example, the second metal oxide semiconductor material may be any of the above metal oxides (such as indium zinc oxide, indium tin oxide, indium gallium zinc oxide, indium zinc tin oxide and indium gallium tin oxide) doped with one or a combination of the 17 rare earth elements listed above. These metal oxides may also be doped or not doped with X.

The first material layer 12a may be formed by sputtering using the above selected materials. The second material layer 12b may be formed by co-sputtering using a simple substance or a compound, corresponding to the doped rare earth element (e.g., in a case where the rare earth element is praseodymium (Pr), the simple substance corresponding to the rare earth element is the simple substance praseodymium (Pr), and the compound corresponding to the rare earth element is a compound of praseodymium (Pr)), and a metal oxide selected as the second n-type metal oxide semiconductor material under a certain gas atmosphere (such as an oxygen-containing atmosphere), so as to achieve doping of the rare earth element.

In the thin film transistor 1 provided by embodiments of the present disclosure, the material of the first material layer 12a is selected to use a material with the carrier mobility greater than 40 cm²/Vs as the carrier transport layer, so that conductivity of the semiconductor layer 12 may increase, thereby improving the carrier mobility of the thin film transistor 1. Moreover, the first n-type metal oxide semiconductor material in the second material layer 12a is doped with the rare earth element, so that the relaxation path of the photo-generated carriers may be changed, and the activation energy required for the recombination process of photo-generated electron-hole pairs may be reduced. The less the activation energy, the easier the recombination process. In this way, the holes and the electrons are more prone to recombination, thereby improving the negative bias illumination stress (NBIS) stability of the thin film transistor 1. Compared with the related art in which only materials with relatively large carrier mobility are used as the semiconductor layer 12, the NBIS stability of the thin film transistor may be improved while the carrier mobility is taken into account. Compared with the related art in which only materials doped with rare earth elements are used as the semiconductor layer 12, it may be avoided that the carrier mobility of the entire semiconductor layer 12 is reduced caused by the doping of the rare earth elements, and the carrier mobility and the light stability of the semiconductor layer may also be balanced.

In some embodiments, a doping ratio of the Y in the second n-type metal oxide semiconductor material is in a range of 0.01 at % to 0.30 at %, inclusive, where at % represents an atomic percentage content. The doping ratio of the Y in the second n-type metal oxide semiconductor material refers to a percentage of the number of atoms of the rare earth element referred to by Y to the total number of atoms in the second n-type metal oxide semiconductor material.

Here, it will be noted that in a case where a type of rare earth element is selected as the Y, the doping ratio of the Y in the second n-type metal oxide semiconductor material refers to a percentage of the number of atoms of the rare earth element to the total number of atoms in the second n-type metal oxide semiconductor material. In a case where a combination of multiple types of rare earth elements are selected as the Y, the doping ratio of the Y in the second n-type metal oxide semiconductor material refers to a percentage of the number of atoms of the several rare earth elements selected as the Y to the total number of atoms in the second n-type metal oxide semiconductor material.

For example, a rare earth element (e.g., neodymium (Nd)) is selected as the Y, and the second n-type metal oxide semiconductor material is indium zinc tin oxide (ITZO) doped with Y. The doping ratio of the Y in the second n-type metal oxide semiconductor material refers to a percentage of the number of atoms of neodymium (Nd) to the total number of atoms in the second n-type metal oxide semiconductor material. That is, the percentage of the number of atoms of neodymium (Nd) to the total number of atoms in the second n-type metal oxide semiconductor material may be any value in a range of 0.01 at % to 0.3 at %, inclusive. For example, in the second n-type metal oxide semiconductor material, the number of atoms of indium (In) accounts for 1% of the total number of atoms in the second n-type metal oxide semiconductor material, the number of atoms of tin (Sn) accounts for 2% of the total number of atoms in the second n-type metal oxide semiconductor material, the number of atoms of zinc (Zn) accounts for 2% of the total number of atoms in the second n-type metal oxide semiconductor material, and the number of atoms of neodymium (Nd) accounts for 0.17% of the total number of atoms in the second n-type metal oxide semiconductor material. In this case, a ratio of the numbers of atomics of In, Sn, Zn and Nd may be 1:2:2:0.17.

For example, rare earth elements (e.g., neodymium (Nd) and praseodymium (Pr)) are selected as the Y, and the second n-type metal oxide semiconductor material is indium zinc tin oxide (ITZO) doped with Y. The doping ratio of the Y in the second n-type metal oxide semiconductor material refers to a percentage of a sum of the numbers of atoms of both neodymium (Nd) and praseodymium (Pr) to the total number of atoms in the second n-type metal oxide semiconductor material. That is, the percentage of the sum of the number of atoms of both neodymium (Nd) and the number of atoms of praseodymium (Pr) to the total number of atoms in the second n-type metal oxide semiconductor material may be any value in a range of 0.01 at % to 0.3 at %, inclusive. For example, in the second n-type metal oxide semiconductor material, the number of atoms of indium (In) accounts for 1% of the total number of atoms in the second n-type metal oxide semiconductor material, the number of atoms of tin (Sn) accounts for 2% of the total number of atoms in the second n-type metal oxide semiconductor material, the number of atoms of zinc (Zn) accounts for 2% of the total number of atoms in the second n-type metal oxide semiconductor material, the number of atoms of neodymium (Nd) accounts for 0.17% of the total number of atoms in the second n-type metal oxide semiconductor material, and the number of atoms of praseodymium (Pr) accounts for 0.13% of the total number of atoms in the second n-type metal oxide semiconductor material. In this case, the sum of the number of atoms of neodymium (Nd) and the number of atoms of praseodymium (Pr) accounts for 0.3% of the total number of atoms in the second n-type metal oxide semiconductor material.

In some embodiments, the first n-type metal oxide semiconductor material is doped with Z, and Z is selected from one or a combination of rare earth elements. The type of the rare earth element(s) added to the first n-type metal oxide semiconductor material is the same as or different from the type of the rare earth element(s) added to the second n-type metal oxide semiconductor material.

That is, the first n-type metal oxide semiconductor material may also be doped with one or a combination of the 17 rare earth elements (i.e., Z) listed above. In this case, the type of the rare earth element(s) contained in Z may be the same as or different from the type of the rare earth element(s) contained in Y.

For example, in a case where neodymium (Nd) is selected as Y, Z may be neodymium (Nd) or another of the 17 rare earth elements other than neodymium (Nd) or a combination of the 17 rare earth elements.

In these embodiments, the presence of the rare earth element(s) in the first n-type metal oxide semiconductor material may change the relaxation path of the photo-generated carriers in the first material layer 12a, and thus the activation energy required for the recombination process of the photo-generated electron-hole pairs in the first material layer 12a may further be improved, thereby further improving the light stability of the thin film transistor.

In addition, the first material layer 12a may also be formed by co-sputtering using a simple substance or a compound, corresponding to the doped rare earth element (e.g., in a case where the rare earth element is praseodymium (Pr), the simple substance corresponding to the rare earth element is the simple substance praseodymium (Pr), and the compound corresponding to the rare earth element is a compound of praseodymium (Pr)), and a metal oxide selected as the first n-type metal oxide semiconductor material under a certain gas atmosphere (such as an oxygen-containing atmosphere), so as to achieve doping of the rare earth element contained in Z.

The types of elements contained in the first material layer 12a and the types of elements contained in the second material layer 12b may be the same or different, which is not specifically limited here.

In some embodiments, the types of elements included in the first material layer 12a are the same as the types of elements included in the second material layer 12b, and a ratio of the numbers of atomics of all elements included in the first material layer 12a is different from a ratio of the numbers of atomics of all elements included in the second material layer 12b.

For example, the first material layer 12a and the second material layer 12b are both indium zinc tin oxide doped with neodymium (Nd). The ratios of the numbers of atoms of indium and tin in the first material layer 12a (i.e., percentages of the numbers of atoms of indium and tin to the total number of atoms in the first material layer 12a) may be greater than the ratios of the numbers of atoms of indium and tin in the second material layer 12b (i.e., percentages of the numbers of atoms of indium and tin to the total number of atoms in the second material layer 12b). The doping ratio of neodymium (Nd) in the second material layer 12b (i.e., a percentage of the number of atoms of neodymium (Nd) to the total number of atoms in the second material layer 12b) may be greater than the doping ratio of neodymium (Nd) in the first material layer 12a (i.e., a percentage of the number of atoms of neodymium (Nd) to the total number of atoms in the first material layer 12a).

In these embodiments, the target materials used for the first material layer 12a and the second material layer 12b may be the same, and the difference is that during sputtering, different sputtering rates are controlled to achieve material compositions with different ratios of numbers of atomics.

A thickness d1 of the first material layer 12a and a thickness d2 of the second material layer 12b are not specifically limited, as long as the material of the first material layer 12a is selected from the first n-type metal oxide semiconductor materials, and the material of the second material layer 12b is selected from the second n-type metal oxide semiconductor materials.

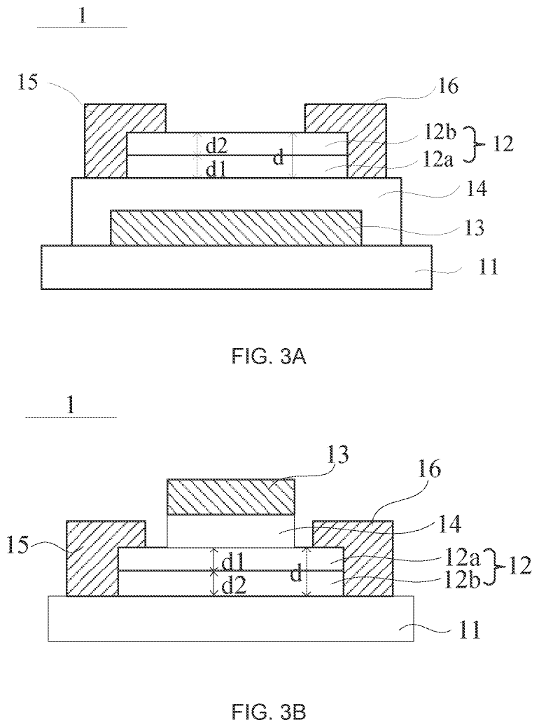

In some embodiments, as shown in FIGS. 3A and 3B, the thickness d2 of the second material layer 12b is greater than 10 nm.

In these embodiments, considering an example where the thickness d of the semiconductor layer 12 is 30 nm, the thickness d2 of the second material layer 12b may be 15 nm, 20 nm, or 25 nm. In this case, correspondingly, the thickness d1 of the first material layer 12a is a difference between the thickness d of the semiconductor layer 12 and the thickness d2 of the second material layer 12b, that is, 15 nm, 10 nm, or 5 nm.

It is found through experiments that by limiting the thickness of the second material layer 12b to be greater than 10 nm, the high carrier mobility of the thin film transistor 1 may be maintained, and the stability of the thin film transistor 1 under the NBIS condition may be improved. For example, the thickness d of the semiconductor layer 12 is 30 nm. In a case where the thickness d1 of the first material layer 12a is 5 nm, and the thickness d2 of the second material layer 12b is 25 nm, the carrier mobility of the thin film transistor 1 may reach 27.2 cm²/Vs, and the threshold voltage of the thin film transistor 1 under NBIS may only shift negatively by 1.56 V. In a case where the thickness d1 of the first material layer 12a is 10 nm, and the thickness d2 of the second material layer 12b is 20 nm, the carrier mobility of the thin film transistor 1 may reach 36.4 cm²/Vs, and the threshold voltage of the thin film transistor 1 under NBIS may only shift negatively by 1.12 V. In a case where the thickness d1 of the first material layer 12a is 15 nm, and the thickness d2 of the second material layer 12b is 15 nm, the carrier mobility of the thin film transistor 1 may reach 49.3 cm²/Vs, and the threshold voltage of the thin film transistor 1 under NBIS may only shift negatively by 1.70 V. In a case where the thickness d1 of the first material layer 12a is 20 nm, and the thickness of the second material layer 12b is 10 nm, although the carrier mobility of the thin film transistor 1 may reach 50.1 cm²/Vs, the NBIS stability of the thin film transistor 1 deteriorates, and the negative shift of the threshold voltage is 9.13 V in the 3600 s test. It can be seen that it may ensure a relatively high carrier mobility of the thin film transistor 1 and the bias stability of the thin film transistor 1 under NBIS by limiting the thickness d2 of the second material layer 12b within the above range. In addition, as the ratio of the thickness d1 of the first material layer 12a to the thickness d2 of the second material layer 12b increases, the carrier mobility of the thin film transistor 1 exhibit an increasing trend, while the NBIS stability of the thin film transistor 1 has no significant change.

In addition, it is found through experiments that by reasonably setting the thickness d1 of the first material layer 12a, the carrier mobility and light stability of the thin film transistor 1 may be balanced without limiting the thickness d1 of the first material layer 12a to be less than 10 nm. This is because that relaxation ability of the rare earth-doped photo-generated electrons in the second material layer 12b is sufficient to relax the overall photo-generated electrons in both the first material layer 12a and the second material layer 12b. Therefore, it may be possible to achieve high mobility and high light stability within a relatively wide range of the thickness d1 of the first material layer 12a without limiting of an excessively thin first material layer 12a, thereby improving the manufacturing uniformity of the first material layer 12a.

In some embodiments, in a case where the thickness d2 of the second material layer 12b is less than or equal to 15 nm, a ratio of the thickness d1 of the first material layer 12a to the thickness d2 of the second material layer 12b is less than or equal to 1.

That is, in a case where the thickness d of the semiconductor layer 12 is 30 nm, the thickness d2 of the second material layer 12b may be 15 nm. In this case, the thickness d1 of the first material layer 12a may also be 15 nm. In this case, the thin film transistor 1 has good bias stability under NBIS.

In some other embodiments, in a case where the thickness d2 of the second material layer 12b is greater than 15 nm, the thickness d1 of the first material layer 12a is greater than or equal to 20 nm, and the ratio of the thickness d1 of the first material layer 12a to the thickness d2 of the second material layer 12b is less than or equal to 2.

In these embodiments, considering an example where the thickness d1 of the first material layer 12a is 20 nm, the thickness d2 of the second material layer 12b may be 20 nm or 30 nm.

It is found through experiments that by keeping the thickness d1 of the first material layer 12a greater than 20 nm, in a case where the thickness d2 of the second material layer 12b is greater than 15 nm, and the ratio of the thickness d1 of the first material layer 12a to the thickness d2 of the second material layer 12b is less than or equal to 2, the bias stability of the thin film transistor 1 under NBIS may be improved while a relatively high carrier mobility of the thin film transistor 1 is ensured.

For example, in a case where the thickness d1 of the first material layer 12a is 20 nm, the thickness d2 of the second material layer 12b may be 16 nm, 20 nm, 25 nm or 30 nm. It is found through experiments that in a case where the thickness d1 of the first material layer 12a is 20 nm and the thickness d2 of the second material layer 12b is 20 nm, the carrier mobility of the thin film transistor 1 may reach 50.1 cm²/Vs, and the threshold voltage of the thin film transistor under NBIS may shift negatively by 4.66 V. In a case where the thickness d1 of the first material layer 12a is 20 nm and the thickness d2 of the second material layer 12b is 30 nm, the carrier mobility of the thin film transistor 1 may reach 47.0 cm²/Vs, and the threshold voltage of the thin film transistor 1 under NBIS may only shift negatively by 1.56 V. It can be known from the above that in a case where the thickness d1 of the first material layer 12a is 20 nm, by increasing the thickness d2 of the second material layer 12b, the NBIS stability of the thin film transistor 1 may be improved. Moreover, the continuous increase in thickness d2 of the second material layer 12b will not affect the carrier mobility of the thin film transistor 1. In addition, as the thickness d2 of the second material layer 12b continues to increase, the bias stability of the thin film transistor 1 under NBIS shows an increasing trend.

In order to avoid insufficient uniformity caused by excessively thin thickness d1 of the first material layer 12a, in some embodiments, the thickness d1 of the first material layer 12a is greater than or equal to 10 nm.

In some embodiments, the thickness d of the semiconductor layer 12 is in a range of 30 nm to 70 nm, inclusive, which may meet application requirements.

Based on the above specific implementations, in order to objectively evaluate technical effects of the technical solutions provided in the present disclosure, the following will provide detailed and exemplary description of the technical solutions provided in the present disclosure through comparative examples and experimental examples.

### Comparative Example 1

A manufacturing method for a thin film transistor in Comparative Example 1 is as follows.
In step 1), a p-type heavily doped silicon is selected as a bottom gate (i.e., the gate 13) and a substrate 11, and after ultrasonic cleaning and drying, a layer of SiO₂ with a thickness of 100 nm is grown as a gate insulating layer 14.
In step 2), an indium zinc tin oxide (ITZO, In:Sn:Zn=2:1:2, i.e., a ratio of the numbers of atoms of In, Sn and Zn is 2:1:2) film is deposited on the gate insulating layer 14. The thickness is 30 nm, and the magnetron sputtering deposition parameters are as follows: direct current (DC) power 80 W, argon flow 20 sccm (short for standard cubic centimeter per minute), oxygen flow 10 sccm, and working pressure 0.18 Pa. The indium zinc tin oxide (ITZO, In:Sn:Zn=2:1:2) film is patterned to obtain a semiconductor layer 12.
In step 3), a source 15 and a drain 16 (e.g., an indium tin oxide (ITO) film) are deposited on the substrate on which the semiconductor layer 12 is formed by magnetron sputtering, and a thickness thereof is 100 nm. A mask process is used to define a width and a length of the channel of the semiconductor layer 12 of the thin film transistor 1 as 800 μm and 400 μm, respectively.
In step 4), heat treatment is performed at 350° C. for 1 hour (h) in an air atmosphere to complete annealing, so as to obtain an ITZO thin film transistor.

### Comparative Example 2

A manufacturing method of a thin film transistor in Comparative Example 2 is substantially the same as the manufacturing method of the thin film transistor 1 in Comparative Example 1. The difference is that the material of the semiconductor layer 12 in step 2) of Comparative Example 2 is praseodymium-doped indium zinc tin oxide (ITZO:Pr, In:Sn:Zn:Pr=1:2:2:0.17, i.e., a ratio of the numbers of atoms of In, Sn, Zn and Pr is 1:2:2:0.17), and the magnetron sputtering deposition parameters are as follows: radio frequency (RF) power 80 W, argon flow 15 sccm, and working pressure 0.1 Pa.

### Experimental Example 1

A manufacturing method of a thin film transistor 1 in Experimental Example 1 is substantially the same as the manufacturing method of the thin film transistor 1 in Comparative Example 1. The difference is that the semiconductor layer 12 in step 2) of Experimental Example 1 includes a first material layer 12a and a second material layer 12b, a material of the first material layer 12a is indium zinc tin oxide (ITZO, In:Sn:Zn=2:1:2), and a material of the second material layer 12b is praseodymium-doped indium zinc tin oxide (ITZO:Pr, In:Sn:Zn:Pr=1:2:2:0.17). A thickness d1 of the first material layer 12a is 5 nm, and a thickness d2 of the second material layer 12b is 25 nm. The manufacturing method of the first material layer 12a may refer to the manufacturing method of the indium zinc tin oxide (ITZO) film in Comparative Example 1, and the manufacturing method of the second material layer 12b may refer to the manufacturing method of the praseodymium-doped indium zinc tin oxide (ITZO:Pr, In:Sn :Zn:Pr=1:2:2:0.17) film in Comparative Example 2.

### Experimental Example 2

A manufacturing method of a thin film transistor in Experimental Example 2 is substantially the same as the manufacturing method of the thin film transistor in Experimental Example 1. The difference is that in Experimental Example 2, the thickness d1 of the first material layer 12a is 10 nm, and the thickness d2 of the second material layer 12b is 20 nm.

### Experimental Example 3

A manufacturing method of a thin film transistor in Experimental Example 3 is substantially the same as the manufacturing method of the thin film transistor in Experimental Example 1. The difference is that in Experimental Example 3, the thickness d1 of the first material layer 12a is 15 nm, and the thickness d2 of the second material layer 12b is 15 nm.

### Experimental Example 4

A manufacturing method of a thin film transistor in Experimental Example 4 is substantially the same as the manufacturing method of the thin film transistor in Experimental Example 1. The difference is that in Experimental Example 4, the thickness d1 of the first material layer 12a is 20 nm, and the thickness d2 of the second material layer 12b is 10 nm.

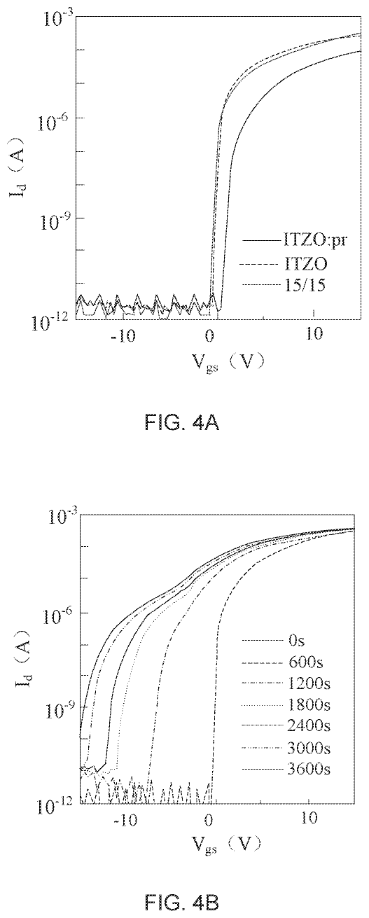

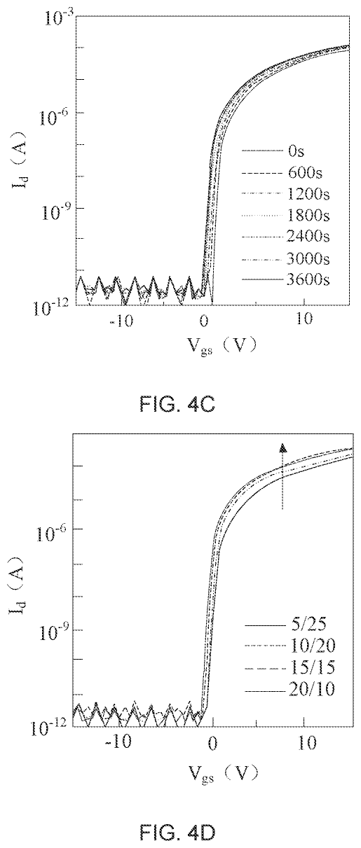

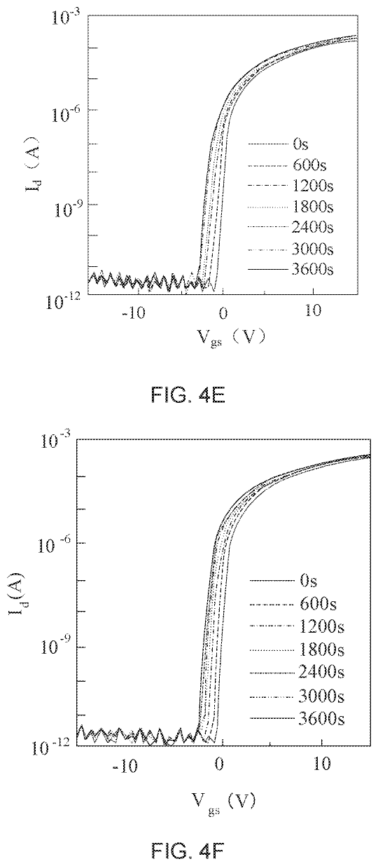

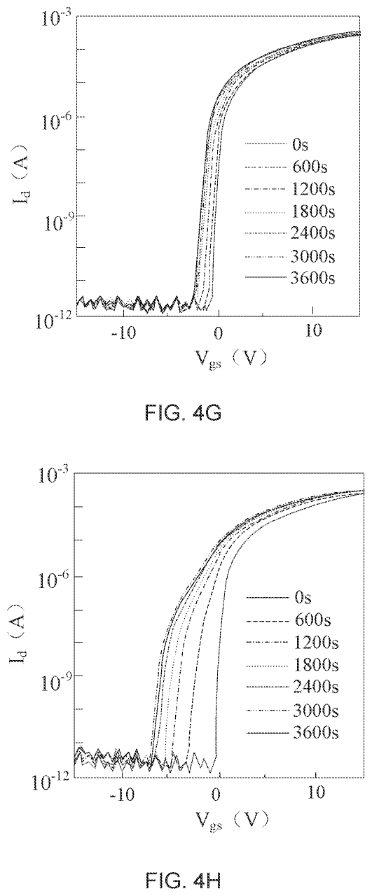

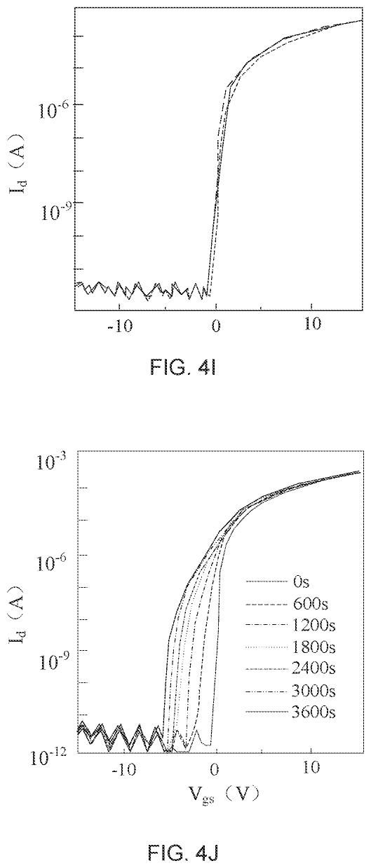

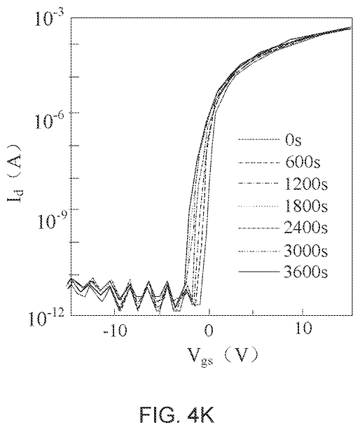

As shown in FIG. 4A, the thin film transistor with single-layer semiconductor layer indium zinc tin oxide (ITZO) manufactured in Comparative Example 1 has a carrier mobility UFE of 51.6 cm²/Vs, a subthreshold swing (SS) of 0.15 V/dec, and an on/off current ratio (Iₒₙ/I_{off}) of 1.31×10⁸. As shown in FIG. 4B, the thin film transistor with single-layer semiconductor layer indium zinc tin oxide (ITZO) manufactured in Comparative Example 1 has relatively poor negative bias illumination stress (NBIS) stability, and the negative shift of the threshold voltage ΔVₜₕ is greater than 15V in the 3600 s test.

As shown in FIG. 4A, the thin film transistor with single-layer semiconductor layer praseodymium-doped indium zinc tin oxide (ITZO:Pr) manufactured in Comparative Example 2 has a carrier mobility μ_{FE} of 16.2 cm²/Vs, a subthreshold swing (SS) of 0.20 V/dec, and an on/off current ratio (Iₒₙ/I_{off}) of 0.28×10⁸. As shown in FIG. 4C, for the negative bias illumination stress (NBIS) stability of the thin film transistor with single-layer semiconductor layer praseodymium-doped indium zinc tin oxide (ITZO:Pr) manufactured in Comparative Example 2, the negative shift of the threshold voltage ΔVₜₕ is only 0.71 V in the 3600 s test.

As shown in FIG. 4D, the thin film transistor with the double-layer semiconductor layer ITZO/ITZO:Pr (the thickness d1 of the first material layer (ITZO) in the two layers is 5 nm, and the thickness d2 of the second material layer (ITZO:Pr) in the two layers is 25 nm) manufactured in Experimental Example 1 has a carrier mobility μ_{FE} as high as 27.2 cm²/Vs, a subthreshold swing (SS) as low as 0.22 V/dec, and an on/off current ratio (Iₒₙ/I_{off}) as high as 0.85×10⁸. As shown in FIG. 4E, the thin film transistor 1 with the double-layer semiconductor layer ITZO/ITZO:Pr (the thickness d1 of the first material layer in the two layers is 5 nm, and the thickness d2 of the second material layer in the two layers is 25 nm) manufactured in Experimental Example 1 has an excellent negative bias illumination stress (NBIS) stability, and the negative shift of the threshold voltage ΔVₜₕ is only 1.56 V in the 3600 s test.

As shown in FIG. 4D, the thin film transistor with the double-layer semiconductor layer ITZO/ITZO:Pr (the thickness d1 of the first material layer (ITZO) in the two layers is 10 nm, and the thickness d2 of the second material layer (ITZO:Pr) in the two layers is 20 nm) manufactured in Experimental Example 2 has a carrier mobility μ_{FE} as high as 36.4 cm²/Vs, a subthreshold swing (SS) as low as 0.15 V/dec, and an on/off current ratio (Iₒₙ/I_{off}) as high as 1.18×10⁸. As shown in FIG. 4F, the thin film transistor with the double-layer semiconductor layer ITZO/ITZO:Pr (the thickness d1 of the first material layer in the two layers is 10 nm, and the thickness d2 of the second material layer in the two layers is 20 nm) manufactured in Experimental Example 2 has an excellent negative bias illumination stress (NBIS) stability, and the negative shift of the threshold voltage ΔVₜₕ is only 1.12 V in the 3600 s test.

As shown in FIG. 4D, the thin film transistor with the double-layer semiconductor layer ITZO/ITZO:Pr (the thickness d1 of the first material layer (ITZO) in the two layers is 15 nm, and the thickness d2 of the second material layer (ITZO:Pr) in the two layers is 15 nm) manufactured in Experimental Example 3 has a carrier mobility μ_{FE} as high as 49.3 cm²/Vs, a subthreshold swing (SS) as low as 0.19 V/dec, and an on/off current ratio (Iₒₙ/I_{off}) as high as 1.70×10⁸. As shown in FIG. 4G, the thin film transistor with the double-layer semiconductor layer ITZO/ITZO:Pr (the thickness d1 of the first material layer (ITZO) in the two layers is 15 nm, and the thickness d2 of the second material layer (ITZO:Pr) in the two layers is 15 nm) manufactured in Experimental Example 3 has an excellent negative bias illumination stress (NBIS) stability, and the negative shift of the threshold voltage ΔVₜₕ is only 1.70 V in the 3600 s test.

As shown in FIG. 4D, the thin film transistor with the double-layer semiconductor layer ITZO/ITZO:Pr (the thickness d1 of the first material layer (ITZO) in the two layers is 20 nm, and the thickness d2 of the second material layer (ITZO:Pr) in the two layers is 10 nm) manufactured in Experimental Example 4 has a carrier mobility μ_{FE} as high as 50.1 cm²/Vs, a subthreshold swing (SS) as low as 0.25 V/dec, and an on/off current ratio (Iₒₙ/I_{off}) as high as 1.03×10⁸. As shown in FIG. 4H, for the negative bias illumination stress (NBIS) stability of the thin film transistor with the double-layer semiconductor layer ITZO/ITZO:Pr (the thickness d1 of the first material layer (ITZO) in the two layers is 20 nm, and the thickness d2 of the second material layer (ITZO:Pr) in the two layers is 10 nm) manufactured in Experimental Example 4, the negative shift of the threshold voltage ΔVₜₕ is 5.75 V in the 3600 s test.

The performance parameters of the thin film transistors in the above Comparative Examples 1 to 2 and Experimental Examples 1 to 4 are shown in Table 1 below.

TABLE 1

| | Vₜₕ | μ_{FE} | SS | Iₒₙ/I_{off} | |
|---|---|---|---|---|---|
| d1/d2 | (V) | (cm²/Vs) | (V/dec) | (×10⁸) | NBIS |
| 5 nm/25 nm | 0.22 | 27.2 | 0.22 | 0.85 | −1.56 |
| 10 nm/20 nm | 0.02 | 36.4 | 0.15 | 1.18 | −1.12 |
| 15 nm/15 nm | −0.30 | 49.3 | 0.19 | 1.70 | −1.7 |
| 20 nm/10 nm | −0.05 | 50.1 | 0.25 | 1.03 | −5.75 |
| ITZO:Pr | 1.16 | 16.2 | 0.20 | 0.28 | −0.71 |
| ITZO | −0.14 | 51.6 | 0.15 | 1.31 | −15 |

In combination with Table 1 and FIGS. 4A to 4F, by providing two material layers, in a case where the thickness of the semiconductor layer 12 is constant, it is possible to balance the high carrier mobility of the first material layer 12a and the good negative bias illumination stress stability of the second material layer 12b. In addition, as the ratio of the thickness d1 of the first material layer 12a to the thickness d2 of the second material layer 12b increases, the carrier mobility μ_{FE} increases, while the NBIS stability has no significant change. In a case where the ratio of the thickness d1 of the first material layer 12a to the thickness d2 of the second material layer 12b is 15 nm/15 nm, the thin film transistor has rather good performance.

### Experimental Example 5

A manufacturing method of a thin film transistor in Experimental Example 5 is substantially the same as the manufacturing method of the thin film transistor in Experimental Example 1. The difference is that in Experimental Example 5, the thickness d1 of the first material layer 12a is 20 nm, and the thickness d2 of the second material layer 12b is 20 nm.

### Experimental Example 6

A manufacturing method of a thin film transistor in Experimental Example 6 is substantially the same as the manufacturing method of the thin film transistor in Experimental Example 1. The difference is that in Experimental Example 6, the thickness d1 of the first material layer 12a is 20 nm, and the thickness d2 of the second material layer 12b is 30 nm.

As shown in FIG. 4I, the thin film transistor with the double-layer semiconductor layer ITZO/ITZO:Pr (the thickness d1 of the first material layer (ITZO) in the two layers is 20 nm, and the thickness d2 of the second material layer (ITZO:Pr) in the two layers is 20 nm) manufactured in Experimental Example 5 has a carrier mobility μ_{FE} as high as 47.0 cm²/Vs, a subthreshold swing (SS) as low as 0.20 V/dec, and an on/off current ratio (Iₒₙ/I_{off}) as high as 1.16×10⁸. As shown in FIG. 4J, the thin film transistor with the double-layer semiconductor layer ITZO/ITZO:Pr (the thickness d1 of the first material layer (ITZO) in the two layers is 20 nm, and the thickness d2 of the second material layer (ITZO:Pr) in the two layers is 20 nm) manufactured in Experimental Example 5 has the negative shift of the threshold voltage ΔVₜₕ of 4.66 V in the 3600 s test.

As shown in FIG. 4I, the thin film transistor with the double-layer semiconductor layer ITZO/ITZO:Pr (the thickness d1 of the first material layer (ITZO) in the two layers is 20 nm, and the thickness d2 of the second material layer (ITZO:Pr) in the two layers is 30 nm) manufactured in Experimental Example 6 has a carrier mobility μ_{FE} as high as 47.0 cm²/Vs, a subthreshold swing (SS) as low as 0.17 V/dec, and an on/off current ratio (Iₒₙ/I_{off}) as high as 0.88×10⁸. As shown in FIG. 4K, the thin film transistor with the double-layer semiconductor layer ITZO/ITZO:Pr (the thickness d1 of the first material layer (ITZO) in the two layers is 20 nm, and the thickness d2 of the second material layer (ITZO:Pr) in the two layers is 30 nm) manufactured in Experimental Example 6 has an excellent negative bias illumination stress (NBIS) stability, and the negative shift of the threshold voltage ΔVₜₕ is only 1.56 V in the 3600 s test.

The performance parameters of the thin film transistors in the above Experimental Examples 4 to 6 are shown in Table 2 below.

TABLE 2

| | Vₜₕ | μ_{FE} | SS | Iₒₙ/I_{off} | |
|---|---|---|---|---|---|
| d1/d2 | (V) | (cm²/Vs) | (V/dec) | (×10⁸) | NBIS |
| 20 nm/10 nm | −0.05 | 50.1 | 0.25 | 1.03 | −5.75 |
| 20 nm/20 nm | −0.27 | 47.0 | 0.20 | 1.16 | −4.66 |
| 20 nm/30 nm | −0.04 | 47.0 | 0.17 | 0.88 | −1.56 |

It can be seen in combination with FIG. 4I to FIG. 4K and Table 2 that in a case where the thickness d1 of the first material layer 12a remains constant at 20 nm, the increasing of the thickness d2 of the second material layer 12b may significantly improve the NBIS stability, while the carrier mobility μ_{FE} has no significant change. In a case where the ratio of the thickness d1 of the first material layer 12a to the thickness d2 of the second material layer 12b is 20 nm/30 nm, the thin film transistor has rather good performance.

### Comparative Example 3

A manufacturing method of a thin film transistor in Comparative Example 3 is substantially the same as the manufacturing method of the thin film transistor 1 in Comparative Example 2. The difference is that the material of the semiconductor layer 12 in Comparative Example 3 is terbium-doped indium zinc tin oxide (ITZO:Tb, In:Sn:Zn : Tb=1:2:2:0.15, i.e., a ratio of the numbers of atoms of In, Sn, Zn and Tb is 1:2:2:0.15).

### Experimental Example 7

A manufacturing method of a thin film transistor in Experimental Example 7 is substantially the same as the manufacturing method of the thin film transistor in Experimental Example 1. The difference is that in Experimental Example 7, the material of the second material layer 12b is terbium-doped indium zinc tin oxide (ITZO:Tb, In:Sn :Zn:Tb=1:2:2:0.15, i.e., the ratio of the numbers of atoms of In, Sn, Zn and Tb is 1:2:2:0.15), the thickness d1 of the first material layer 12a is 10 nm, and the thickness d2 of the second material layer 12b is 20 nm.

The thin film transistor with single-layer semiconductor layer indium zinc tin oxide (ITZO:Tb) manufactured in Comparative Example 3 has a carrier mobility μ_{FE} of 17.4 cm²/Vs, a subthreshold swing (SS) of 0.25 V/dec, and an on/off current ratio (Iₒₙ/I_{off}) of 0.29×10⁸. For the negative bias illumination stress (NBIS) stability of the thin film transistor with single-layer semiconductor layer indium zinc tin oxide (ITZO:Tb) manufactured in Comparative Example 3, the negative shift of the threshold voltage ΔVₜₕ is only 1.12 V in the 3600 s test.

The thin film transistor with the double-layer semiconductor layer ITZO/ITZO:Tb (the thickness d1 of the first material layer (ITZO) in the two layers is 10 nm, and the thickness d2 of the second material layer (ITZO:Tb) in the two layers is 20 nm) manufactured in Experimental Example 7 has a carrier mobility μ_{FE} as high as 39.1 cm²/Vs, a subthreshold swing (SS) as low as 0.17 V/dec, and an on/off current ratio (Iₒₙ/I_{off}) as high as 1.23×10⁸. The thin film transistor with the double-layer semiconductor layer ITZO/ITZO:Tb (the thickness d1 of the first material layer (ITZO) in the two layers is 10 nm, and the thickness d2 of the second material layer (ITZO:Tb) in the two layers is 20 nm) manufactured in Experimental Example 7 has a good negative bias illumination stress (NBIS) stability, and the negative shift of the threshold voltage ΔVₜₕ is 2.13 V in the 3600 s test. The performance parameters of the thin film transistors in Comparative Example 1, Comparative Example 3 and Experimental Example 7 are shown in Table 3 below.

TABLE 3

| | Vₜₕ | μ_{FE} | SS | Iₒₙ/I_{off} | |
|---|---|---|---|---|---|
| d1/d2 | (V) | (cm²/Vs) | (V/dec) | (×10⁸) | NBIS |
| 10 nm/20 nm | −0.21 | 39.1 | 0.17 | 1.23 | −2.13 |
| ITZO:Tb | 0.41 | 17.4 | 0.25 | 0.29 | −1.12 |
| ITZO | −0.14 | 51.6 | 0.15 | 1.31 | −15 |

It can be seen from Table 3 that by providing two material layers, the material of the first material layer 12a being a ITZO material, and the material of the second material layer being a terbium-doped indium zinc tin oxide (ITZO:Tb) material, it may also be possible to balance the high carrier mobility of the first material layer 12a and the good negative bias illumination stress stability of the second material layer 12b.

To sum up, the first material layer 12a and the second material layer 12b are provided, the material of the first material layer 12a is selected from materials with high carrier mobility and used as a front channel layer, and the material of the second material layer 12b is an n-type metal oxide semiconductor material doped with rare earth elements and used as a back channel layer. Thus, the high carrier mobility of the material of the first material layer 12a and the good stability under NBIS of the material of the second material layer 12b may be combined, and the obtained thin film transistor 1 may balance the carrier mobility and the light stability, thereby improving the overall performance of the thin film transistor 1. In addition, by reasonably setting the thickness d1 of the first material layer 12a and the thickness d2 of the second material layer 12b, relaxation ability of the photo-generated electrons in the second material layer 12b is sufficient to relax the overall photo-generated electrons in both the first material layer 12a and the second material layer 12b, so that good light stability of the thin film transistor may be ensured, and a wide range of the thickness d1 of the first material layer 12a may be maintained to avoid uncontrollable uniformity during manufacturing caused by the excessively small thickness d1 of the first material layer 12a.

The foregoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

1. A thin film transistor, comprising:
a substrate; and
a semiconductor layer, a gate, a source and a drain that are disposed on the substrate; wherein
the semiconductor layer includes a first material layer and a second material layer that are stacked; a material of the first material layer is selected from one or a combination of first n-type metal oxide semiconductor materials, and a material of the second material layer is selected from one or a combination of second n-type metal oxide semiconductor materials;
a carrier mobility of a first n-type metal oxide semiconductor material is greater than or equal to 40 cm²/Vs; a second n-type metal oxide semiconductor material is doped with Y, and the Y is selected from one or a combination of rare earth elements; and
the first material layer is closer to the gate than the second material layer.

2. The thin film transistor according to claim 1, wherein
a doping ratio of the Y in the second n-type metal oxide semiconductor material is in a range of 0.01 at % to 0.30 at %, inclusive.

3. The thin film transistor according to claim 1, wherein
the first n-type metal oxide semiconductor material is doped with Z, the Z is selected from one or a combination of rare earth elements, and a type of a rare earth element added to the first n-type metal oxide semiconductor material is same as or different from a type of a rare earth element added to the second n-type metal oxide semiconductor material.

4. The thin film transistor according to claim 1, wherein
types of elements included in the first material layer are same as types of elements included in the second material layer, and a ratio of numbers of atomics of all elements included in the first material layer is different from a ratio of numbers of atomics of all elements included in the second material layer.

5. The thin film transistor according to claim 1, wherein
the first n-type metal oxide semiconductor material is selected from metal oxides doped with X or not doped with X; and
the metal oxides each include one or more of an indium element, a zinc element, a tin element and a gallium element, and an oxide element; and the X is selected from one or a combination of an aluminum element, a tungsten element, a hafnium element, a tantalum element, a zirconium element, a nitrogen element and a hydrogen element.

6. The thin film transistor according to claim 1, wherein
a thickness of the second material layer is greater than 10 nm.

7. The thin film transistor according to claim 6, wherein
the thickness of the second material layer is greater than 10 nm and less than or equal to 15 nm, and a ratio of a thickness of the first material layer to the thickness of the second material layer is less than or equal to 1.

8. The thin film transistor according to claim 7, wherein
as the ratio of the thickness of the first material layer to the thickness of the second material layer gradually increases, a carrier mobility of the thin film transistor increases.

9. The thin film transistor according to claim 6, wherein
the thickness of the second material layer is greater than 15 nm, a thickness of the first material layer is greater than or equal to 20 nm, and a ratio of the thickness of the first material layer to the thickness of the second material layer is less than or equal to 2.

10. The thin film transistor according to claim 1, wherein
a thickness of the first material layer is greater than or equal to 10 nm.

11. The thin film transistor according to claim 1, wherein
a thickness of the semiconductor layer is in a range of 30 nm to 70 nm, inclusive.

12. A display panel, comprising the thin film transistor according to claim 1.

13. A display device, comprising the display panel according to claim 12.

14. The thin film transistor according to claim 1, wherein a type of rare earth element is selected as the Y, and the doping ratio of the type of rare earth element in the second n-type metal oxide semiconductor material is in a range of 0.01 at % to 0.30 at %, inclusive.

15. The thin film transistor according to claim 1, wherein a combination of multiple types of rare earth elements are selected as the Y, and the doping ratio of the combination of the multiple types of rare earth elements in the second n-type metal oxide semiconductor material is in a range of 0.01 at % to 0.30 at %, inclusive.
